(19) United States
(12) Patent Application Publication
(10) Pub. No.: US 2026/0181875 A1
(43) Pub. Date: Jun. 25, 2026

(54) SEMICONDUCTOR DEVICE

(71) Applicant: Samsung Electronics Co., Ltd., Suwon-si (KR)

(72) Inventors: Yangdoo Kim, Suwon-si (KR); Gwang-Hyun Baek, Suwon-si (KR); Jungeun Shin, Suwon-si (KR); Jinkwan Lee, Suwon-si (KR); Je-Woo Han, Suwon-si (KR)

(21) Appl. No.: 19/337,234

(22) Filed: Sep. 23, 2025

(30) Foreign Application Priority Data
Dec. 23, 2024 (KR) 10-2024-0194666

(51) Int. Cl. H10B 12/00; H10D 1/68

(52) U.S. Cl. CPC H10B 12/488; H10B 12/482; H10D 1/714; H10B 12/05

(57) ABSTRACT

A semiconductor device a plurality of semiconductor patterns on a substrate and extending in a first direction parallel to an upper surface of the substrate, the plurality of semiconductor patterns are spaced apart in a third direction, a bit line extending in the third direction and electrically connected to a first end of each of the plurality of semiconductor patterns, a plurality of word lines on the plurality of semiconductor patterns and extending in a second direction parallel to the upper surface of the substrate, a plurality of first electrodes extending in the first direction and spaced apart in the third direction, each of the plurality of first electrodes has a first end electrically connected to a second end of a corresponding semiconductor pattern and a supporter extending in the third direction and covering a second end of each of the plurality of first electrodes.

### CROSS-REFERENCE TO RELATED APPLICATION

This application claims priority to and the benefit of Korean Patent Application No. 10-2024-0194666 filed with the Korean Intellectual Property Office on Dec. 23, 2024, the entire contents of which are incorporated herein by reference.

### BACKGROUND

Technologies are being developed to increase the integration density of semiconductor devices. For two-dimensional semiconductor memory devices, the integration density is mainly determined by the area occupied by the unit memory cell, and this aspect of integration density can be affected by the level of fine pattern formation technology.

However, since the fine pattern formation technology requires expensive equipment, the integration of two-dimensional semiconductor devices is increasing, but is still limited. Accordingly, three-dimensional semiconductor devices having three-dimensionally arranged memory cells have been proposed.

### SUMMARY

Some aspects of the present disclosure provide semiconductor devices with improved reliability.

Some aspects of the present disclosure provide semiconductor devices that exhibit reduced structural deformation.

A semiconductor device according to some implementations of the present disclosure includes a substrate, a plurality of semiconductor patterns on the substrate and extending in a first direction parallel to an upper surface of the substrate, wherein the plurality of semiconductor patterns are spaced apart in a third direction perpendicular to the upper surface of the substrate, a bit line extending in the third direction and electrically connected to a first end of each of the plurality of semiconductor patterns, a plurality of word lines on the plurality of semiconductor patterns and extending in a second direction parallel to the upper surface of the substrate, wherein the second direction intersects the first direction, a plurality of first electrodes extending in the first direction and spaced apart in the third direction, wherein each of the plurality of first electrodes has a first end electrically connected to a second end of a corresponding semiconductor pattern of the plurality of semiconductor patterns and a supporter extending in the third direction and covering a second end of each of the plurality of first electrodes.

According to some implementations of the present disclosure, a semiconductor device includes a substrate, a plurality of semiconductor patterns on the substrate and extending in a first direction parallel to an upper surface of the substrate, wherein the plurality of semiconductor patterns are spaced apart in a third direction perpendicular to the upper surface of the substrate, a bit line extending in the third direction and electrically connected to a first end of each of the plurality of semiconductor patterns, a plurality of word lines on the plurality of semiconductor patterns and extending in a second direction parallel to the upper surface of the substrate, wherein the second direction intersects the first direction, a plurality of first electrodes having a rod shape and extending in the first direction, wherein each of the plurality of first electrodes has a first end electrically connected to a second end of a corresponding semiconductor pattern of the plurality of semiconductor patterns, a supporter extending in the third direction and in contact with a second end of each of the plurality of first electrodes, a second electrode on the plurality of first electrodes and the supporter, and a dielectric film between the plurality of first electrodes and the second electrode.

According to some implementations of the present disclosure, a semiconductor device includes a substrate, a plurality of semiconductor patterns on the substrate and extending in a first direction parallel to an upper surface of the substrate, wherein the plurality of semiconductor patterns are spaced apart in a third direction perpendicular to the upper surface of the substrate, a bit line extending in the third direction and electrically connected to a first end of each of the plurality of semiconductor patterns, a plurality of word lines on the semiconductor patterns and extending in a second direction parallel to the upper surface of the substrate, wherein the second direction intersects the first direction, a plurality of first electrodes extending in the first direction and having a cylinder shape with a hollow center portion, wherein each of the plurality of first electrodes has a first end electrically connected to a second end of a corresponding semiconductor pattern of the plurality of semiconductor patterns, a supporter extending in the third direction and covering a second end of each of the plurality of first electrodes, a second electrode on the plurality of first electrode and the supporter, and a dielectric film between the plurality of first electrodes and the second electrode.

### BRIEF DESCRIPTION OF THE DRAWINGS

FIG. 1 is a perspective view schematically illustrating an example of a semiconductor device.

FIG. 2 is a cross-sectional view of an example of a semiconductor device.

FIG. 3 is an enlarged view of area A of FIG. 2.

FIG. 4 is a plan view of a portion of an example of a semiconductor device.

FIG. 5 is a side view of a portion of an example of a semiconductor device.

FIG. 6 to FIG. 23 are drawings illustrating an example of a method for manufacturing a semiconductor device.

FIG. 24 is a plan view of a portion of an example of a semiconductor device

FIG. 25 is a side view of a portion of an example of a semiconductor device.

FIG. 26 is a plan view of a portion of an example of a semiconductor device

FIG. 27 is a side view of a portion of an example of a semiconductor device.

FIG. 28 to FIG. 30 are side views of portions of an example of a semiconductor device.

### DETAILED DESCRIPTION

For clarity of explanation, parts irrelevant to the description are omitted, and the same reference numerals are used for identical or similar components throughout the specification.

In addition, the size and thickness of each component shown in the drawings may be arbitrarily shown for convenience of explanation. In the drawings, the thickness of layers, films, panels, regions, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

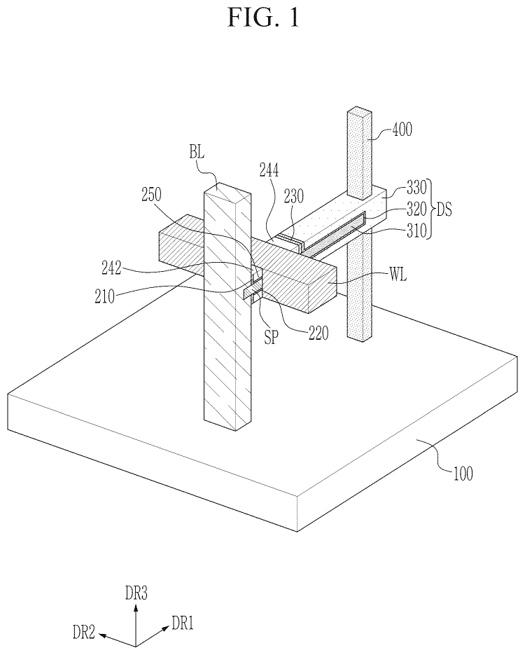

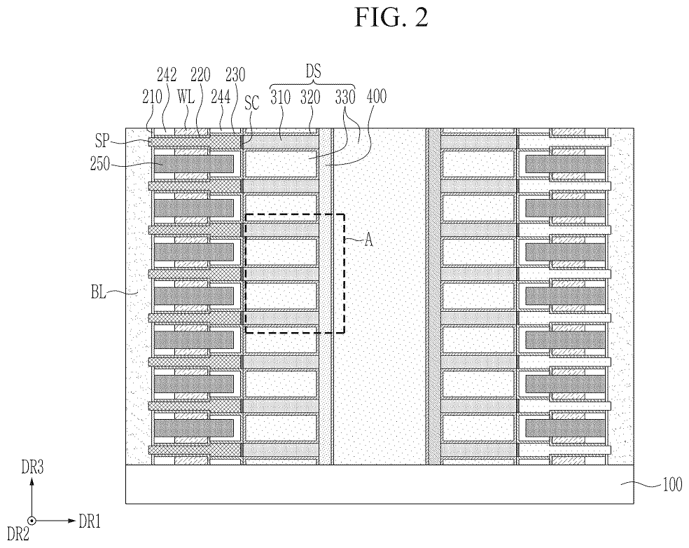

FIG. 1 is a perspective view schematically illustrating an example of a semiconductor device. FIG. 2 is a cross-sectional view of the semiconductor device.

As shown in FIGS. 1-2, a semiconductor device may include a substrate 100, a bit line BL, a semiconductor pattern SP, and a word line WL.

For convenience of explanation, FIG. 1 illustrates one bit line BL, one word line WL, a semiconductor pattern SP, and a data storage element DS, and or more insulating layers that may be present are omitted.

The substrate 100 may be, for example, a silicon substrate, a germanium substrate, or a silicon-germanium substrate. The substrate 100 may have a shape extending in a first direction DR1 and a second direction DR2. Here, the second direction DR2 may be a direction intersecting the first direction DR1. For example, the first direction DR1 and the second direction DR2 can be orthogonal to each other. For example, the first direction DR1 and the second direction DR2 may be directions parallel to the upper surface of the substrate 100, e.g., lateral directions. Additional peripheral circuitry besides that shown may be provided on the substrate 100.

A bit line BL extending in a third direction DR3 may be positioned on the upper surface of the substrate 100. The bit line BL may have a shape extending in a third direction DR3 that is perpendicular to the upper surface of the substrate 100. Here, the third direction DR3 may be a direction intersecting the first direction DR1 and the second direction DR2. For example, the second direction DR2 and the third direction DR3 can be orthogonal to each other. The third direction DR3 and the first direction DR1 can be orthogonal to each other. For example, the third direction DR3 may be a direction perpendicular to the upper surface of the substrate 100, e.g., a vertical direction.

The bit line BL may include a conductive material. The conductive material can be, for example, one of a doped semiconductor material such as doped silicon (doped Si) or doped germanium (doped Ge), a conductive metal nitride such as titanium nitride (TiN) or tantalum nitride (TaN), a metal such as tungsten (W), titanium (Ti), or tantalum (Ta), or a metal-semiconductor compound such as tungsten silicide (WSiₓ), cobalt silicide (CoSiₓ), or titanium silicide (TiSiₓ).

In FIG. 1 and FIG. 2, one bit line BL is arranged on the substrate 100, but the number of bit lines BL is not limited thereto. For example, a plurality of bit lines BL can be arranged spaced apart from each other in the first direction DR1 and the second direction DR2 on the substrate 100.

A semiconductor pattern SP can be positioned on the substrate 100. The semiconductor pattern SP may have a shape extending in the first direction DR1. For example, the semiconductor pattern SP may have a bar shape extending in the first direction DR1.

The semiconductor pattern SP can be connected (e.g., electrically connected) to the bit line BL. One end of the semiconductor pattern SP can be connected to the bit line BL, e.g., in contact with the bit line BL. The semiconductor pattern SP can be arranged to penetrate the first insulating layer 210. For example, one end of the semiconductor pattern SP can be capped by the bit line BL. However, the relative arrangement is not limited to this. For example, one end of the semiconductor pattern SP may be in contact with one side of the bit line BL.

For example, the semiconductor pattern SP may include silicon (Si), germanium (Ge), or silicon-germanium (SiGe).

Multiple semiconductor patterns SP may be included. Each of the semiconductor patterns SP may include a channel region, a first impurity region, and a second impurity region. The first impurity region and the second impurity region may represent regions in which the semiconductor pattern SP is doped with impurities. The first impurity region and the second impurity region can have a conductivity type of n-type or p-type.

One end of the semiconductor pattern SP can be connected to a bit line BL, e.g., in contact with the bit line BL. The semiconductor pattern SP may be connected to the bit line BL such that the semiconductor pattern SP partially protrudes inside the bit line BL, but the arrangement is not limited thereto. For example, the side surface of one end of the semiconductor pattern SP may not protrude into the bit line BL and may be in contact with the side surface of the bit line BL.

The other end of the semiconductor pattern SP can be connected (e.g., electrically connected) to a data storage element DS. For example, a first impurity region of the semiconductor pattern SP may be connected to the bit line BL, and a second impurity region of the semiconductor pattern SP may be connected to the data storage element DS. A channel region may be located between the first impurity region and the second impurity region.

A plurality of semiconductor patterns SP may be arranged on a substrate 100, and the plurality of semiconductor patterns SP may be stacked so as to be spaced apart from each other along the third direction DR3. For example, a plurality of semiconductor patterns SP connected to one bit line BL can be arranged to be spaced apart from each other along a third direction DR3. Additionally, a plurality of semiconductor patterns SP may be arranged to be spaced apart from each other in the first direction DR1 and the second direction DR2 along corresponding bit lines BL that are arranged to be spaced apart from each other in the first direction DR1 and the second direction DR2.

A word line WL can be arranged on the semiconductor pattern SP. The word line WL may have a shape extending along the second direction DR2. For example, the word line WL may have a bar shape extending along the second direction.

For example, a word line WL may be positioned to surround a portion of a semiconductor pattern SP. However, the arrangement is not limited thereto, and for example, a pair of word lines may be arranged respectively above and below the semiconductor pattern SP. A plurality of word lines WL may be arranged on the substrate 100, and the plurality of word lines WL may be stacked while being spaced apart from each other in the third direction DR3.

A word line WL may include a conductive material. The conductive material can be any one of a semiconductor material, a conductive metal nitride, a metal, or a metal-semiconductor compound.

The semiconductor device may include a first insulating layer 210, a gate insulating pattern 220, a second insulating layer 230, a first spacer 242, a second spacer 244, and an interlayer insulating layer 250.

The first insulating layer 210 may be placed on one side of the bit line BL. The first insulating layer 210 may be located between the bit line BL and the first spacer 242. In addition, the first insulating layer 210 may be located between the bit line BL and the interlayer insulating layer 250.

The gate insulating pattern 220 may be placed between the word line WL and the semiconductor pattern SP. The semiconductor pattern SP and the word line WL can be arranged to be spaced apart in the third direction DR3 with the gate insulating pattern 220 interposed therebetween. The gate insulating pattern 220 may be further positioned between the first spacer 242 and the semiconductor pattern SP. The gate insulating pattern 220 may be further positioned between the word line WL and the second spacer 244. For example, the gate insulating pattern 220 may have an “L” shape in the cross-section in the first direction DR1 and the third direction DR3, but the shape is not limited thereto.

The gate insulating pattern 220 may include an insulating material. The gate insulating pattern 220 may include a silicon oxide film, a silicon oxynitride film, a high-k film having a higher dielectric constant than the silicon oxide film, or a combination thereof. Here, the high-k dielectric film can be made of a metal oxide or a metal oxide nitride. For example, a high-k dielectric film that can be used as a gate insulating pattern 220 may include, but is not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or a combination thereof.

The second insulating layer 230 may be located between the second spacer 244 and the semiconductor pattern SP. The second insulating layer 230 may be positioned between the second spacer 244 and the data storage element DS. For example, the second insulating layer 230 may have an “L” shape in the cross-section in the first direction DR1 and the third direction DR3, but is not limited thereto.

The first spacer 242 may be positioned between the word line WL and the bit line BL. The first spacer 242 may have a shape that surrounds a portion of the semiconductor pattern SP between the word line WL and the bit line BL. The first spacer 242 may be located between the first insulating layer 210 and the word line WL.

The second spacer 244 may be positioned between the word line WL and the data storage element DS. For example, the first spacer 242 and the second spacer 244 can be positioned on both (or opposite) sides of the word line WL. The second spacer 244 may have a form that surrounds a portion of the semiconductor pattern SP between the word line WL and the data storage element DS. The second spacer 244 may be positioned between the second insulating layer 230 and the interlayer insulating layer 250.

The first insulating layer 210, the second insulating layer 230, the first spacer 242, and the second spacer 244 may include an insulating material. The first insulating layer 210, the second insulating layer 230, the first spacer 242, and the second spacer 244 may include the same insulating material. Alternatively, at least one of the first insulating layer 210, the second insulating layer 230, the first spacer 242, and the second spacer 244 may include a different insulating material from other(s) of the first insulating layer 210, the second insulating layer 230, the first spacer 242, and the second spacer 244. For example, the first insulating layer 210, the second insulating layer 230, the first spacer 242, and the second spacer 244 may include, but are not limited to, at least one of silicon oxide (SiO), silicon nitride (SiN), or silicon oxynitride (SiON). The first insulating layer 210, the second insulating layer 230, the first spacer 242, and the second spacer 244 may be formed simultaneously or may be formed separately.

The interlayer insulating layer 250 may be placed between semiconductor patterns SP, e.g., between adjacent semiconductor patterns SP. The plurality of semiconductor patterns SP may be arranged to be spaced apart in the third direction DR3, and an interlayer insulating layer 250 may be arranged between pairs of the plurality of semiconductor patterns SP spaced apart in the third direction DR3.

The interlayer insulating layer 250 may be positioned over a word line WL. The interlayer insulating layer 250 may be positioned over the first spacer 242. The interlayer insulating layer 250 may be positioned between word lines WL. For example, a plurality of word lines WL may be arranged to be spaced apart in the third direction DR3, and an interlayer insulating layer 250 may be arranged between pairs of the plurality of word lines WL spaced apart in the third direction DR3. The interlayer insulating layer 250 may be located between the second spacer 244 and the bit line BL. The interlayer insulating layer 250 may be positioned between the second spacer 244 and the first insulating layer 210. One side of the interlayer insulating layer 250 can be in contact with the first insulating layer 210, and the other side of the interlayer insulating layer 250 can be in contact with the second spacer 244.

The interlayer insulation layer 250 may include an insulating material. For example, the interlayer insulating layer 250 may include, but is not limited to, at least one of silicon oxide (SiO), silicon nitride (SiN), or silicon oxynitride (SiON).

A silicide layer SC may be disposed between the first electrode 310 and the semiconductor pattern SP. The silicide layer SC can be located at the other end of the semiconductor pattern SP. The silicide layer SC can play a role in reducing the contact resistance between the first electrode 310 and the semiconductor pattern SP. The silicide layer SC may include a silicon metal compound. The silicide layer SC may include, for example, a compound in which silicon (Si) and at least one of titanium (Ti), cobalt (Co), or nickel (Ni) are combined. The silicide layer SC may include, for example, titanium silicide (TiSiₓ).

The semiconductor device may include the data storage element DS and a supporter 400. The data storage element DS can be connected (e.g., electrically connected) to a semiconductor pattern SP. The other end of the semiconductor pattern SP can be connected (e.g., electrically connected) to the data storage element DS. The data storage element DS may include a first electrode 310, a dielectric film 320, and a second electrode 330.

The first electrode 310 can be connected to the other end of the semiconductor pattern SP. One end of the first electrode 310 can be connected to a semiconductor pattern SP. The first electrode 310 may have a shape extending in the first direction DR1. The first electrode 310 may have a bar, rod, or pillar shape extending in the first direction DR1, but is not limited thereto. For example, the first electrode 310 may have a cylinder shape with a hollow center. The first electrode 310 may be positioned at substantially the same vertical level as the semiconductor pattern SP. The first electrode 310 can be aligned parallel to the semiconductor pattern SP along the first direction DR1. The width of the first electrode 310 in the second direction DR2 or the third direction DR3 may be substantially the same as the width of the semiconductor pattern SP in the second direction DR2 or the third direction DR3, but is not limited thereto. For example, the width of the first electrode 310 in the second direction DR2 or the third direction DR3 may be different from the width of the semiconductor pattern SP in the second direction DR2 or the third direction DR3.

The first electrode 310 may include a conductive material. The first electrode 310 may include, for example, at least one of a metal material such as titanium (Ti), tantalum (Ta), tungsten (W), copper (Cu), aluminum (Al), platinum (Pt), iridium (Ir), or ruthenium (Ru), a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

The supporter 400 can be positioned on the substrate 100. The supporter 400 may have a form extending in the third direction DR3. The supporter 400 can perform the role of supporting the first electrode 310. The supporter 400 can be connected to (e.g., in contact with) the other end of the first electrode 310. The supporter 400 can cover the other end of the first electrode 310. One side of the supporter 400 can come into contact with the other side of the first electrode 310. The supporter 400 can be connected to (e.g., in contact with) a plurality of first electrodes 310 stacked in the third direction DR3.

The supporter 400 can be arranged parallel to the bit line BL. The supporter 400 can be positioned so as not to overlap the first electrode 310 in the second direction DR2 and the third direction DR3. For example, the supporter 400 may not be located in the space between the plurality of first electrodes 310. The supporter 400 may be positioned to overlap the center area of the first electrode 310 in the second direction DR2 and the first direction DR1, but is not limited thereto.

The supporter 400 may include an insulating material. For example, the supporter 400 may include, but is not limited to, at least one of silicon oxide (SiO), silicon nitride (SiN), or silicon oxynitride (SiON).

The dielectric film 320 can be positioned on the first electrode 310 and the supporter 400. The dielectric film 320 can cover the upper and lower surfaces of the first electrode 310 and one or more side surfaces of the supporter 400. For example, the side of the first electrode 310 may mean a surface that is perpendicular to the upper surface of the substrate 100. The dielectric film 320 may cover a portion of the other side of the first electrode 310. Here, the other side of the first electrode 310 may mean a surface opposite to one side of the first electrode 310 where the first electrode 310 and the semiconductor pattern SP are connected. For example, a part of the other side of the first electrode 310 may be covered by the supporter 400, and another part may be covered by the dielectric film 320. The dielectric film 320 may be positioned between the first electrode 310 and the second electrode 330. The dielectric film 320 can be conformally placed on the first electrode 310 and the supporter 400.

The dielectric film 320 can be placed on the second insulating layer 230. The first spacer 242 and the second spacer 244 may be placed on the interlayer insulating layer 250, the second insulating layer 230 may be placed on the second spacer 244, and the dielectric film 320 may be placed on the second insulating layer 230. For example, the second spacer 244 may be placed on a side surface of the interlayer insulating layer 250.

The dielectric film 320 may include an insulating material. The dielectric film 320 may include a silicon oxide film, a silicon oxynitride film, a high-k dielectric film having a higher dielectric constant than the silicon oxide film, or a combination thereof. Here, the high-k dielectric film can be made of a metal oxide or a metal oxide nitride. For example, high-k dielectric films usable as the dielectric film 320 may include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or combinations thereof.

The second electrode 330 may be positioned on the dielectric film 320. The second electrode 330 can fill the space between the plurality of first electrodes 310. The data storage elements DS stacked in the third direction DR3 can share one second electrode 330.

The second electrode 330 may include a conductive material. The second electrode 330 may include, for example, at least one of a metal material such as titanium (Ti), tantalum (Ta), tungsten (W), copper (Cu), aluminum (Al), platinum (Pt), iridium (Ir), or ruthenium (Ru), a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

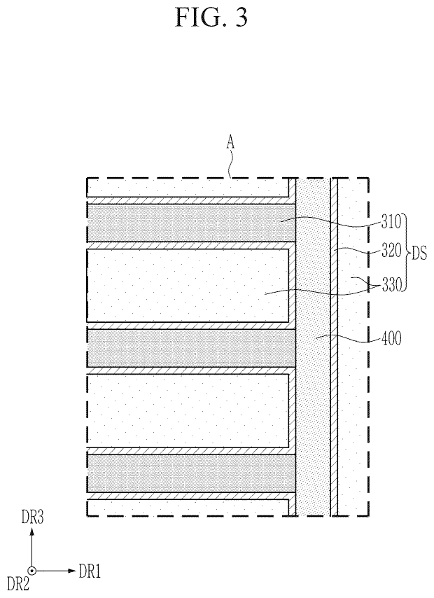

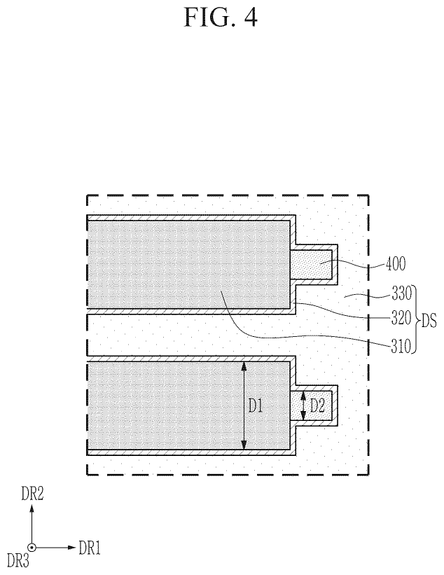

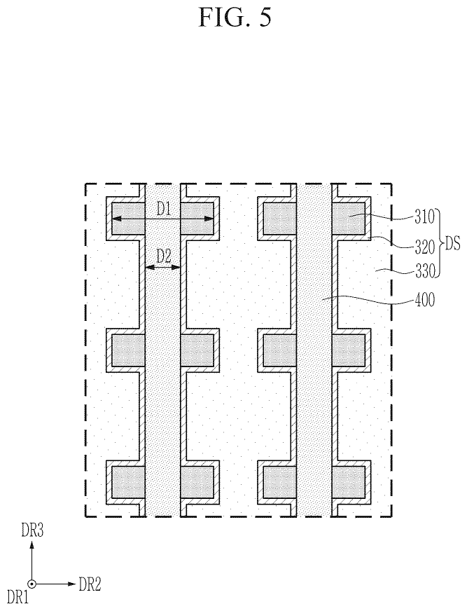

FIG. 3 is an enlarged view of area A of FIG. 2. FIG. 4 is a plan view of an example of a semiconductor device, e.g., the semiconductor device of FIGS. 1-2. FIG. 5 is a side view of a portion of the semiconductor device.

Referring to FIG. 3 to FIG. 5, a plurality of first electrodes 310 having a shape extending in the first direction DR1 can be arranged in parallel and spaced apart in the third direction DR3. The other side of the first electrode 310 can be connected to (e.g., in contact with) the supporter 400. The supporter 400 may have a form extending in the third direction DR3. One supporter 400 can be connected to first electrodes 310 spaced apart in a third direction DR3. The supporter 400 can be positioned to cover the center area of the second direction DR2 of the first electrode 310. The second direction DR2 width D1 of the first electrode 310 may be larger than the second direction DR2 width D2 of the supporter 400.

The supporter 400 can be positioned so as to be non-overlapping with the first electrode 310 along the second direction DR2 and the third direction DR3. The supporter 400 may not be located in the space between the first electrodes 310. The supporter 400 may be positioned so as not to overlap with the first electrode 310 along the second direction DR2 and the third direction DR3, thereby reducing the impact on the data storage capacity of the data storage element DS. However, implementations are not limited thereto, and the supporter 400 may be positioned to overlap the first electrode 310 along the second direction DR2 and/pr the third direction DR3. For example, the supporter 400 may be positioned between adjacent first electrodes 310 of the plurality of first electrodes 310.

The dielectric film 320 can be positioned on the first electrode 310 and the supporter 400. The dielectric film 320 can be conformally placed on the first electrode 310 and the supporter 400. The second electrode 330 may be positioned on the dielectric film 320. The second electrode 330 can fill the space between the plurality of first electrodes 310.

The second electrode 330 can cover the first electrode 310, the supporter 400, and the dielectric film 320 positioned on the first electrode 310 and the supporter 400. The second electrode 330 can fill the space between the plurality of first electrodes 310. For example, the second electrode 330 can fill the space between the plurality of first electrodes 310 in the second direction DR2 and the third direction DR3.

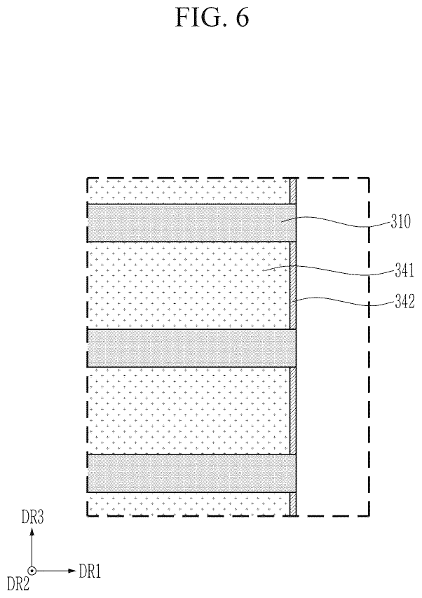

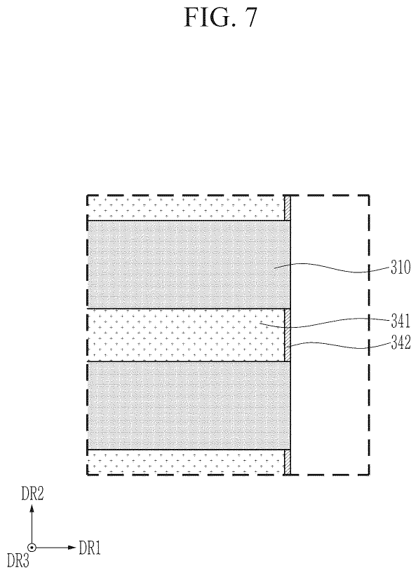

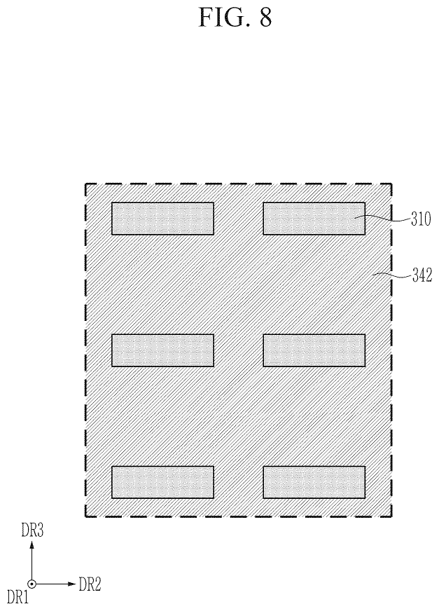

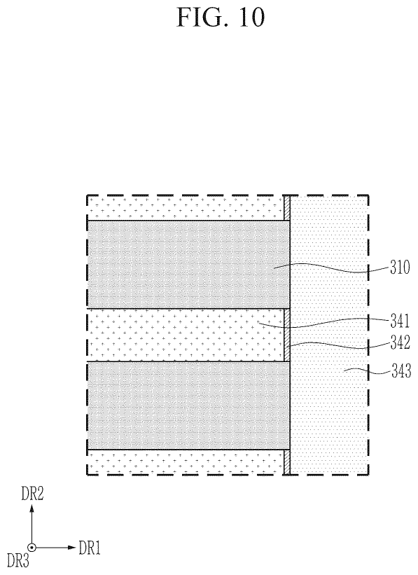

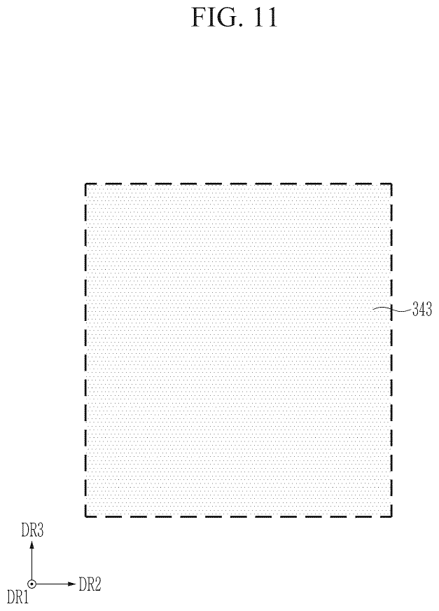

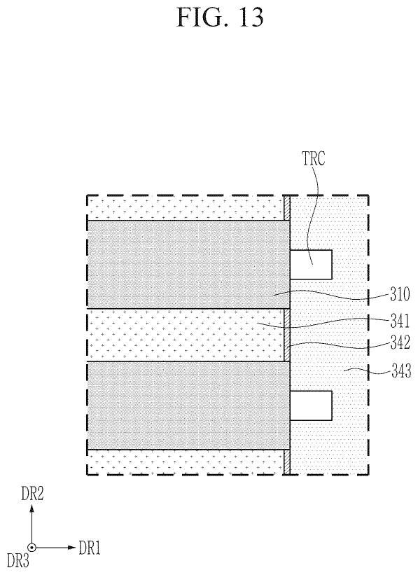

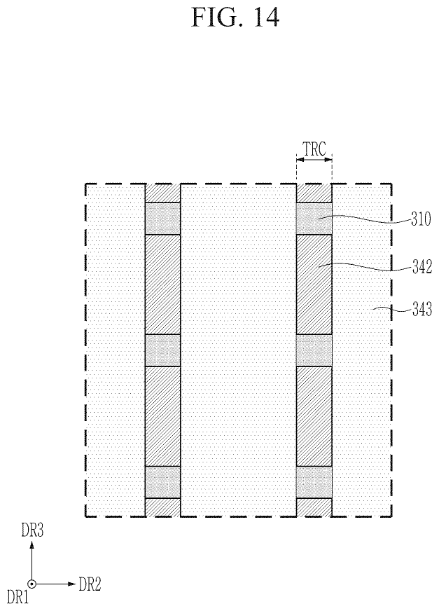

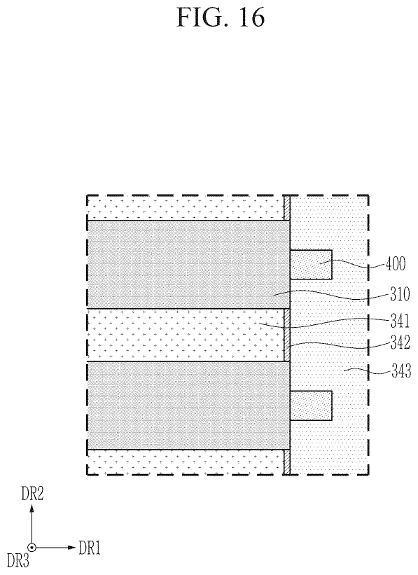

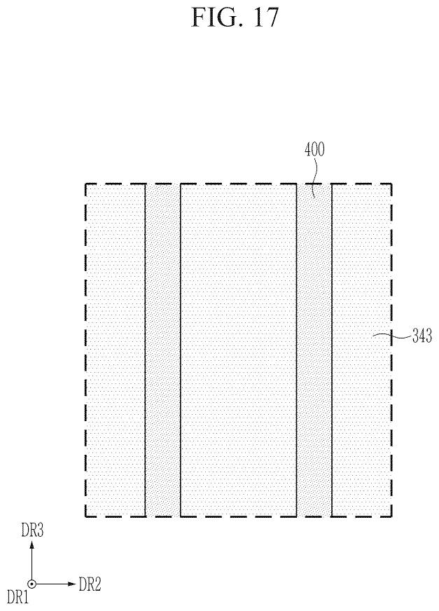

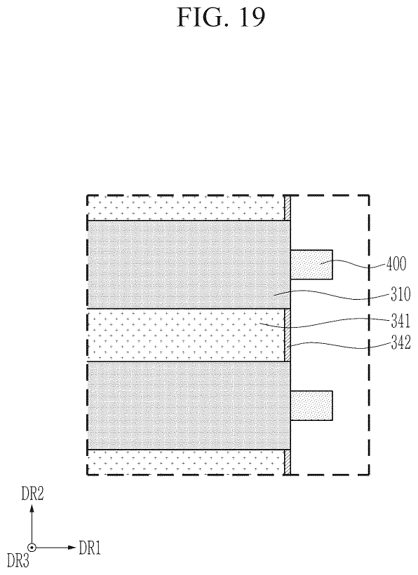

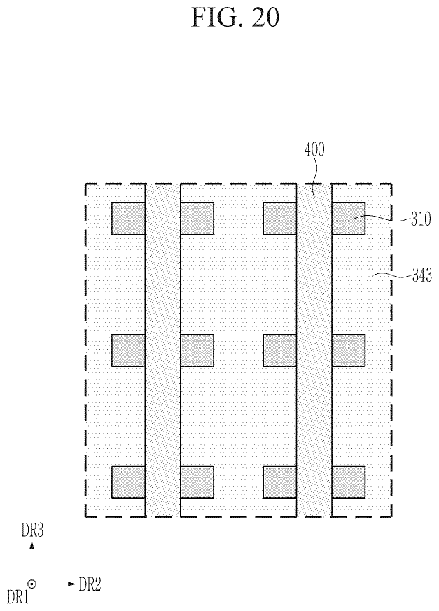

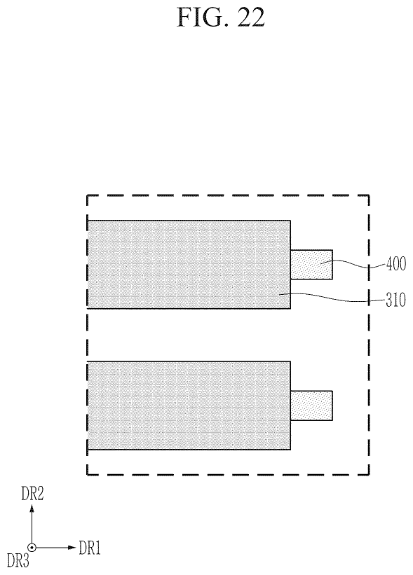

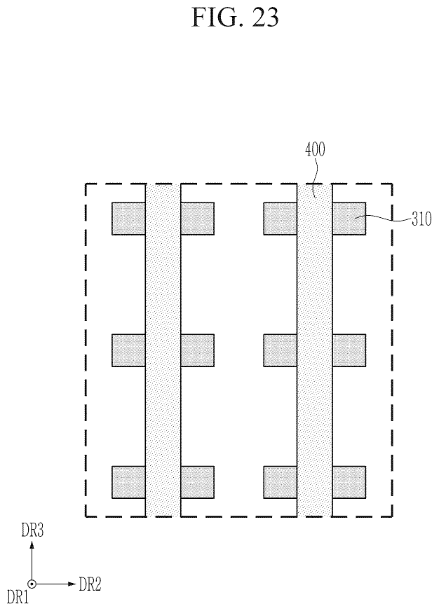

FIG. 6 to FIG. 23 are drawings for explaining an example of a method for manufacturing a semiconductor device, e.g., the semiconductor device of FIGS. 1 to 5.

Referring to FIG. 6 to FIG. 8, first electrodes 310 having a shape extending in a first direction DR1 can be stacked while being spaced apart from each other in a third direction DR3. A first mask pattern 341 and a second mask pattern 342 may be placed between a plurality of first electrodes 310. The first mask pattern 341 can fill a space located between a plurality of first electrodes 310, and the second mask pattern 342 can be conformally arranged on a side surface of the first mask pattern 341. A plurality of first electrodes 310 can be arranged in a form that penetrates the first mask pattern 341 and the second mask pattern 342 in the first direction DR1. The other side of the first electrode 310 may be exposed to the outside. The second mask pattern 342 may have one side exposed to the outside. By the second mask pattern 342, the first mask pattern 341 may not be exposed to the outside. The position of the first mask pattern 341 and the second mask pattern 342 is an example and may be changed in various ways as needed.

The first mask pattern 341 and the second mask pattern 342 may include an insulating material. For example, the first mask pattern 341 and the second mask pattern 342 may include, but are not limited to, at least one of silicon oxide (SiO), silicon nitride (SiN), or silicon oxynitride (SiON). The first mask pattern 341 and the second mask pattern 342 may include different materials. For example, the first mask pattern 341 may include silicon oxide (SiO), and the second mask pattern 342 may include silicon nitride (SiN).

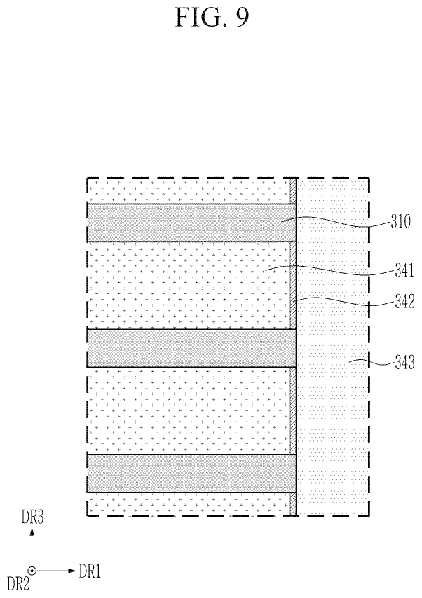

Next, referring to FIG. 9 to FIG. 11, a third mask pattern 343 can be formed to contact the second mask pattern 342 and the first electrode 310. The third mask pattern 343 may have a shape extending in the second direction DR2 and the third direction DR3. The third mask pattern 343 can cover the second mask pattern 342 and the side surface of the first electrode 310 exposed to the outside. The third mask pattern 343 can be formed so as not to overlap with the plurality of first electrodes 310 along the second direction DR2 and the third direction DR3. However, the arrangement is not limited thereto, and a portion of the third mask pattern 343 may be arranged to overlap with a plurality of first electrodes 310 along the second direction DR2 and/or the third direction DR3. For example, in some implementations, the third mask pattern 343 may be positioned between a plurality of first electrodes 310.

The third mask pattern 343 may include an insulating material. For example, the third mask pattern 343 may include, but is not limited to, at least one of silicon oxide (SiO), silicon nitride (SiN), or silicon oxynitride (SiON).

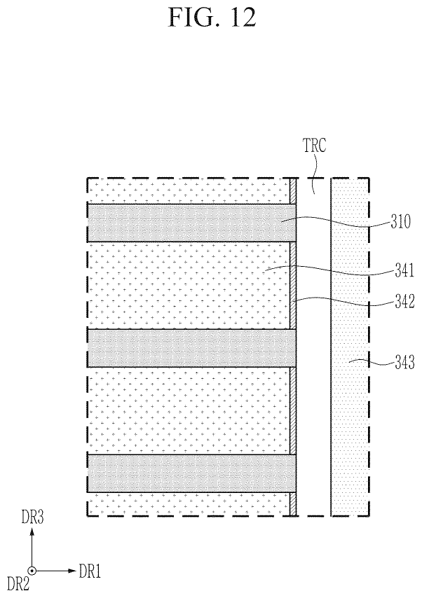

Next, referring to FIG. 12 to FIG. 14, a portion of the third mask pattern 343 may be removed to form a trench TRC. The trench TRC may have a shape extending in the third direction DR3.

The trench TRC can be formed to expose a center region along the second direction DR2 of the first electrode 310. For example, the center area of the second direction DR2 of the first electrode 310 can be exposed by the trench TRC. However, the location of the trench TRC is not limited to this and can be changed in various ways. A portion of the second mask pattern 342 may be exposed by a trench TRC. The trench TRC can be formed to overlap at least a portion of the first electrode 310 in the first direction DR1. The trench TRC can be formed so as not to overlap the first electrode 310 along the second direction DR2 and the third direction DR3. However, implementations are not limited thereto, and the trench TRC may be arranged to overlap the first electrode 310 along the second direction DR2 and/or the third direction DR3. For example, the trench TRC may be located between a plurality of first electrodes 310.

For example, an etching process can be used to form the trench TRC. The etching process may use either a dry etching process and/or a wet etching process, but is not limited thereto and may be performed in various ways.

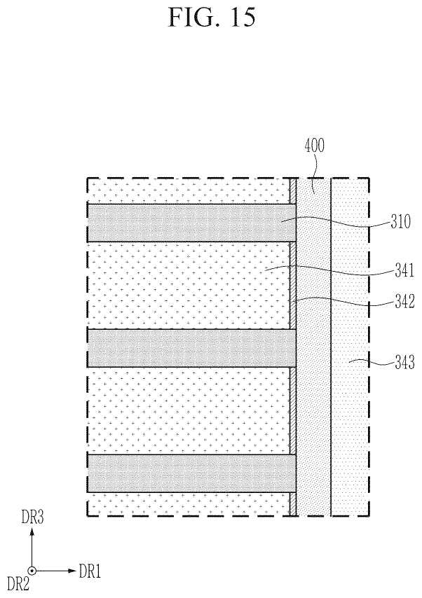

Next, referring to FIG. 15 to FIG. 17, a supporter 400 can be formed within a trench TRC. The supporter 400 may have a form extending in the third direction DR3.

The supporter 400 can be formed to be in contact with the center area of the second direction DR2 of the first electrode 310. However, the location of the trench TRC is not limited to this and can be changed in various ways. The supporter 400 can cover the side surfaces of a plurality of first electrodes 310 stacked in the third direction DR3. A portion of the second mask pattern 342 may come into contact with the supporter 400. The supporter 400 can be covered by a third mask pattern 343. The supporter 400 may be formed to overlap at least a portion of the first electrode 310 along the first direction DR1. The supporter 400 can be formed so as not to overlap the first electrode 310 along the second direction DR2 and the third direction DR3. However, implementations are not limited thereto, and the supporter 400 may be positioned to overlap the first electrode 310 along the second direction DR2 and/or the third direction DR3. For example, the supporter 400 may be positioned between adjacent first electrodes 310 of the plurality of first electrodes 310.

The supporter 400 may include an insulating material. The supporter 400 may include a different material from the third mask pattern 343.

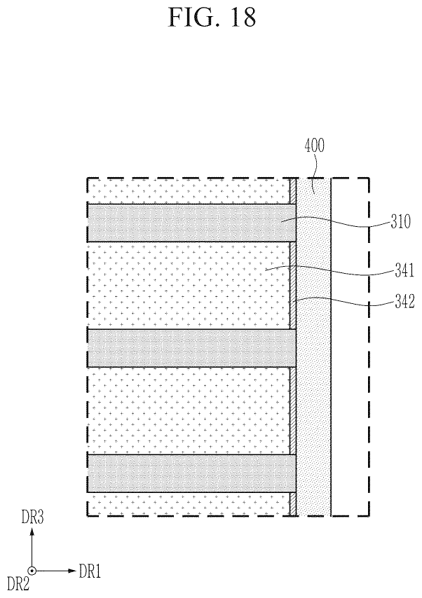

Next, referring to FIG. 18 to FIG. 20, the third mask pattern 343 can be removed. As the third mask pattern 343 is removed, the supporter 400 can be exposed to the outside. Additionally, as the third mask pattern 343 is removed, a portion of the side surface of the first electrode 310 may be exposed. For example, the remaining portion of the side of the first electrode 310 other than the portion in contact with the supporter 400 may be exposed. As the third mask pattern 343 is removed, a portion of the second mask pattern 342 may be exposed to the outside.

For example, an etching process may be performed to remove the third mask pattern 343. The etching process may utilize a dry etching and/or a wet etching method, but is not limited thereto and may be varied in various ways.

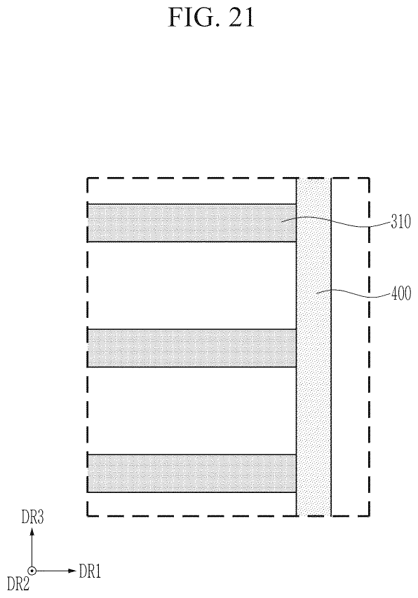

Next, referring to FIG. 21 to FIG. 23, the first mask pattern 341 and the second mask pattern 342 can be removed. As the first mask pattern 341 and the second mask pattern 342 are removed, the first electrode 310 can be exposed to the outside. For example, the upper and lower surfaces of the first electrode 310 may be exposed to the outside. In addition, a surface of the side of the first electrode 310 that was covered by the first mask pattern 341 and the second mask pattern 342 may be exposed to the outside. For example, the side of the first electrode 310 that is covered by the first mask pattern 341 and the second mask pattern 342 may be a surface that extends in the first direction DR1.

For example, the first mask pattern 341 may include silicon oxide (SiO), and the second mask pattern 342 may include silicon nitride (SiN). The supporter 400 may include the same material as the second mask pattern 342. In addition, for example, the width of the supporter 400 may be reduced to some extent in the process of removing the first mask pattern 341 and the second mask pattern 342.

Even if the first mask pattern 341 and the second mask pattern 342 are removed, the supporter 400 is connected to (e.g., in contact with) a plurality of first electrodes 310, so that the first electrodes 310 can be supported. Accordingly, the first electrodes 310 can be prevented from being bent in the third direction DR3 or the like by an external force such as gravity.

When the supporter 400 is formed so as not to overlap with the plurality of first electrodes 310 along the second direction DR2 and the third direction DR3, the impact on data storage performance in the data storage element DS can be reduced by securing the overlapping area of the first electrode 310 and the second electrode 330. However, the arrangement is not limited thereto, and the supporter 400 may overlap with a plurality of first electrodes 310 along the second direction DR2 and/or the third direction DR3. In this case, the supporter 400's support capacity for multiple first electrodes 310 can be further improved.

For example, an etching process may be used to remove the first mask pattern 341 and the second mask pattern 342. The etching process may use a dry etching process and/or a wet etching process, but is not limited thereto and may be performed in various ways.

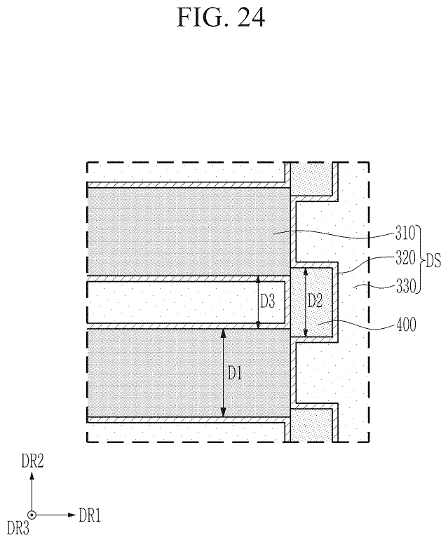

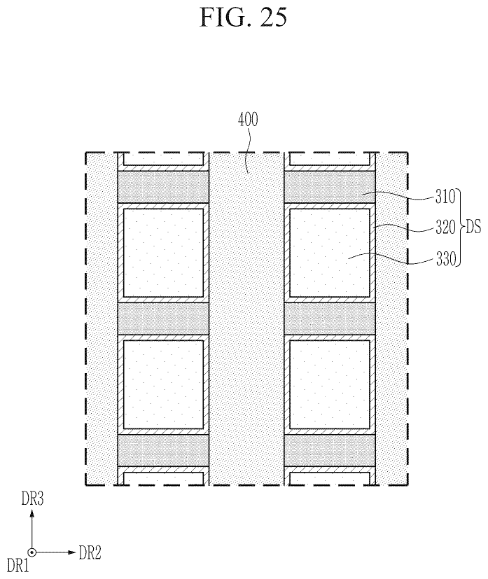

FIG. 24 and FIG. 25 are a plan view and a side view, respectively, illustrating another example of a semiconductor device. The semiconductor device can have characteristics matching or similar to those of the semiconductor device of FIGS. 1 to 5, except where noted otherwise or suggested otherwise by context.

Referring to FIG. 24 and FIG. 25, the supporter 400 may be positioned to overlap at least a portion of the first electrode 310 in the first direction DR1. One supporter 400 can be arranged to overlap simultaneously with a pair of first electrodes 310 spaced apart in the second direction DR2 along the first direction DR1, e.g., adjacent first electrodes 310 in the second direction DR2. The supporter 400 can be positioned to overlap the space between a plurality of first electrodes 310 spaced apart in the second direction DR2 along the first direction DR1. In some implementations, when one supporter 400 is arranged to overlap a pair of first electrodes 310 spaced apart in the second direction DR2 simultaneously in the first direction DR1, the center region (e.g., center) of the first electrode 310 in the second direction DR2 may not come into contact with the supporter 400.

The width D2 of the supporter 400 in the second direction DR2 may be greater than the space D3 between, in the second direction DR2, a pair of first electrodes 310 adjacent in the second direction DR2 at substantially the same level in the third direction DR3. The width D2 of the supporter 400 in the second direction DR2 may be smaller than the width D1 of the first electrode 310 in the second direction DR2.

For example, the supporter 400 may be positioned so as not to overlap the first electrode 310 along the second direction DR2 and the third direction DR3. However, arrangements are not limited thereto, and the supporter 400 may be positioned to overlap the first electrode 310 along the second direction DR2 and/or the third direction DR3. For example, the supporter 400 may be positioned between a plurality of first electrodes 310.

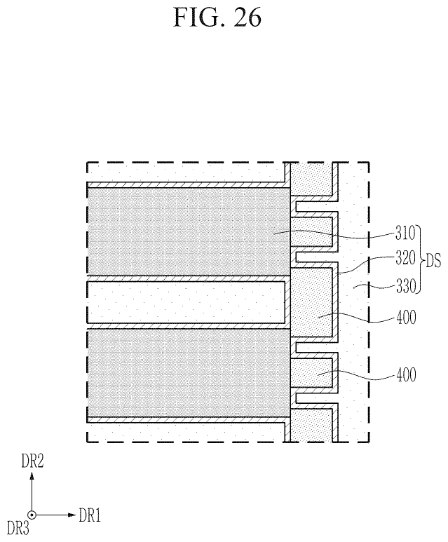

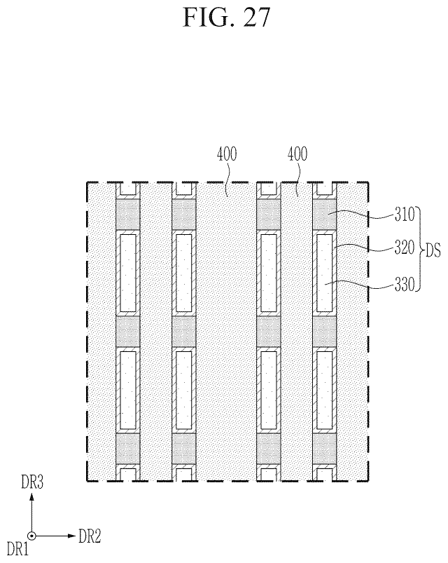

FIG. 26 and FIG. 27 are a plan view and a side view, respectively, illustrating another example of a semiconductor device. The semiconductor device can have characteristics matching or similar to those of the semiconductor device of FIGS. 1 to 5, except where noted otherwise or suggested otherwise by context.

Referring to FIG. 26 and FIG. 27, the supporter 400 may be positioned to overlap the space between a plurality of first electrodes 310 spaced apart in the second direction DR2 and in the first direction DR1. In addition, the supporter 400 may be positioned to overlap the center region (e.g., center) of the first electrode 310 in the second direction DR2 along the first direction DR1. For example, a supporter 400 can be placed at a position overlapping, along the first direction D1, with an area between a pair of first electrodes 310 spaced apart in the second direction DR2, and a supporter 400 can be placed at a position overlapping, along the first direction D1 with a center area (e.g., center) of the first electrode 310 in the second direction DR2.

The width D2 of the supporter 400 in the second direction DR2 may vary depending on the location, but is not limited thereto. That is, the width D2 of the supporter 400 in the second direction DR2 can be substantially the same regardless of the position.

For example, the supporter 400 may be positioned so as not to overlap the first electrode 310 in the second direction DR2 and the third direction DR3. However, without being limited thereto, the supporter 400 may be positioned to overlap the first electrode 310 in the second direction DR2 and the third direction DR3. That is, the supporter 400 may be positioned between a plurality of first electrodes 310.

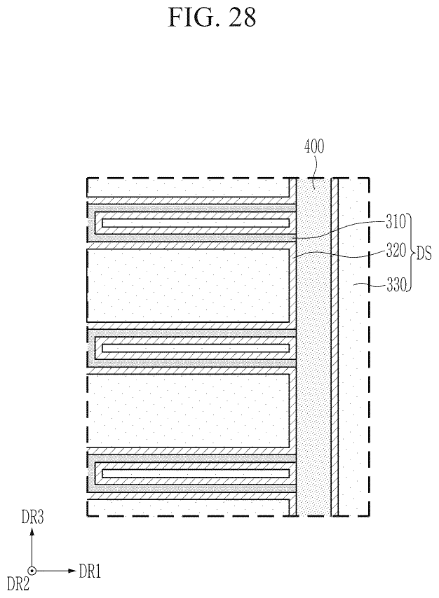

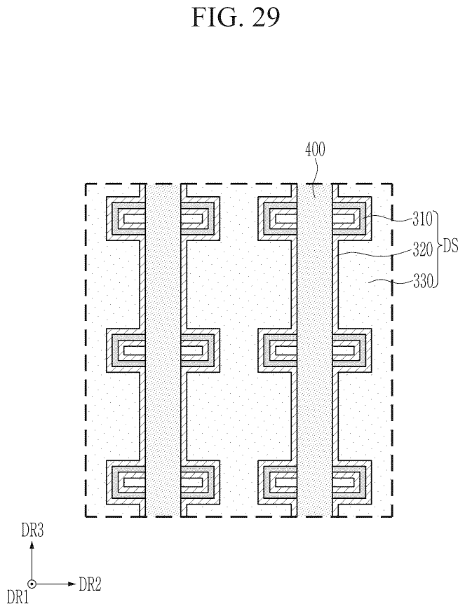

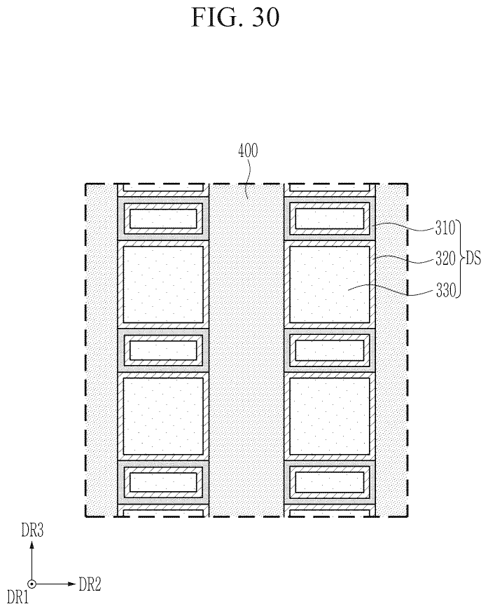

FIG. 28 to FIG. 30 are drawings illustrating another example of a semiconductor device. The semiconductor device can have characteristics matching or similar to those of the semiconductor device of FIGS. 1 to 5, except where noted otherwise or suggested otherwise by context.

Referring to FIG. 28 to FIG. 30, the first electrode 310 may extend in the first direction DR1 and have a cylinder shape with a hollow center portion.

The first electrode 310 may include a vertical portion extending in a third direction DR3 and a horizontal portion extending from the vertical portion in a first direction DR1. The vertical portion of the first electrode 310 can be connected to a semiconductor pattern SP. The vertical portion of the first electrode 310 covers the side surface of the semiconductor pattern SP and can extend in the third direction DR3. The horizontal portion of the first electrode 310 can extend in the first direction DR1 away from the bit line BL from the vertical portion of the first electrode 310. The horizontal portion of the first electrode 310 may have a square pillar shape with a hollow center.

The second electrode 330 may be inserted into the first electrode 310 and surrounded by the first electrode 310. The second electrode 330 can be inserted into the internal space of the cylindrical first electrode 310. The data storage elements DS of multiple layers stacked in the third direction DR3 can share one second electrode 330.

The end of horizontal portion of the first electrode 310 can be supported by a supporter 400. The supporter 400 can come into contact with the dielectric film 320. Even when the first electrode 310 has a cylindrical shape, the end of horizontal portion of the first electrode 310 can be supported by the supporter 400.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although examples have been described in detail above, the scope of the present disclosure is not limited thereto, and various modifications and improvements made by those skilled in the art also fall within the scope of the present disclosure.

What is claimed is:

1. A semiconductor device comprising:
a substrate;
a plurality of semiconductor patterns on the substrate and extending in a first direction parallel to an upper surface of the substrate, wherein the plurality of semiconductor patterns are spaced apart in a third direction perpendicular to the upper surface of the substrate;
a bit line extending in the third direction and electrically connected to a first end of each of the plurality of semiconductor patterns;
a plurality of word lines on the plurality of semiconductor patterns and extending in a second direction parallel to the upper surface of the substrate, wherein the second direction intersects the first direction;
a plurality of first electrodes extending in the first direction and spaced apart in the third direction, wherein each of the plurality of first electrodes has a first end electrically connected to a second end of a corresponding semiconductor pattern of the plurality of semiconductor patterns; and
a supporter extending in the third direction and covering a second end of each of the plurality of first electrodes.

2. The semiconductor device of claim 1, wherein a side surface of the supporter is in contact with a side surface of each of the plurality of first electrodes at the second end of the first electrode.

3. The semiconductor device of claim 1, wherein the supporter overlaps, along the first direction, a center in the second direction of each of the plurality of first electrodes.

4. The semiconductor device of claim 1, wherein a width of the supporter in the second direction is greater than a spacing, in the second direction, between one of the plurality of first electrodes and another first electrode that is spaced apart from the one of the plurality of first electrodes in the second direction.

5. The semiconductor device of claim 4, wherein the supporter overlaps, along the first direction, the one of the plurality of first electrodes and the another first electrode.

6. The semiconductor device of claim 1, further comprising:
a second electrode on the plurality of first electrodes, and
a dielectric film between the plurality of first electrodes and the second electrode.

7. The semiconductor device of claim 1, wherein a width of the supporter in the second direction is smaller than a width of each of the plurality of first electrodes in the second direction.

8. The semiconductor device of claim 1, further comprising:
a silicide layer between each of the plurality of first electrodes and the corresponding semiconductor pattern of the plurality of semiconductor patterns.

9. The semiconductor device of claim 1, wherein each of the plurality of semiconductor patterns and the corresponding first electrode, of the plurality of first electrodes, that is electrically connected to the semiconductor pattern are:
arranged at a same level in the third direction, and
aligned parallel to one another in the first direction.

10. The semiconductor device of claim 1, wherein the supporter is non-overlapping with the plurality of first electrodes along the second direction and the third direction.

11. A semiconductor device comprising:
a substrate;
a plurality of semiconductor patterns on the substrate and extending in a first direction parallel to an upper surface of the substrate, wherein the plurality of semiconductor patterns are spaced apart in a third direction perpendicular to the upper surface of the substrate;
a bit line extending in the third direction and electrically connected to a first end of each of the plurality of semiconductor patterns;
a plurality of word lines on the plurality of semiconductor patterns and extending in a second direction parallel to the upper surface of the substrate, wherein the second direction intersects the first direction;
a plurality of first electrodes having a rod shape and extending in the first direction, wherein each of the plurality of first electrodes has a first end electrically connected to a second end of a corresponding semiconductor pattern of the plurality of semiconductor patterns;
a supporter extending in the third direction and in contact with a second end of each of the plurality of first electrodes;
a second electrode on the plurality of first electrodes and the supporter; and
a dielectric film between the plurality of first electrodes and the second electrode.

12. The semiconductor device of claim 11, wherein the dielectric film is between the supporter and the second electrode.

13. The semiconductor device of claim 11, wherein the supporter overlaps, along the first direction, a center in the second direction of each of the plurality of first electrodes.

14. The semiconductor device of claim 11, wherein the supporter overlaps, along the first direction:
one of the plurality of first electrodes, and
another first electrode that is spaced apart from the one of the plurality of first electrodes in the second direction.

15. The semiconductor device of claim 11, wherein a width of the supporter in the second direction is smaller than a width of each of the plurality of first electrodes in the second direction.

16. A semiconductor device comprising:
a substrate;
a plurality of semiconductor patterns on the substrate and extending in a first direction parallel to an upper surface of the substrate, wherein the plurality of semiconductor patterns are spaced apart in a third direction perpendicular to the upper surface of the substrate;
a bit line extending in the third direction and electrically connected to a first end of each of the plurality of semiconductor patterns;
a plurality of word lines on the semiconductor patterns and extending in a second direction parallel to the upper surface of the substrate, wherein the second direction intersects the first direction;
a plurality of first electrodes extending in the first direction and having a cylinder shape with a hollow center portion, wherein each of the plurality of first electrodes has a first end electrically connected to a second end of a corresponding semiconductor pattern of the plurality of semiconductor patterns;
a supporter extending in the third direction and covering a second end of each of the plurality of first electrodes;
a second electrode on the plurality of first electrode and the supporter; and
a dielectric film between the plurality of first electrodes and the second electrode.

17. The semiconductor device of claim 16, wherein a side surface of the supporter is in contact with a side surface of each of the plurality of first electrodes at the second end of the first electrode.

18. The semiconductor device of claim 16, wherein the supporter overlaps, along the first direction, a center in the second direction of each of the plurality of first electrodes.

19. The semiconductor device of claim 16, wherein the supporter overlaps, along the first direction:
one of the plurality of first electrodes, and
another first electrode that is spaced apart from the one of the plurality of first electrodes in the second direction.

20. The semiconductor device of claim 16, wherein a width of the supporter in the second direction is smaller than a width of each of the plurality of first electrodes in the second direction.
